(19) United States
(12) Patent Application Publication
(10) Pub. No.: US 2010/0073081 A1
(43) Pub. Date: Mar. 25, 2010

(54) INTEGRATED TRACKING FILTER

(75) Inventors: Yo Sub MOON, Suwon (KR); Jeong Ki Choi, Suwon (KR); Yoo Hwan Kim, Yongin (KR); Gyu Suck Kim, Seoul (KR); Kyoung Seok Park, Suwon (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 12/394,677

(22) Filed: Feb. 27, 2009

(30) Foreign Application Priority Data
Sep. 24, 2008 (KR) 10-2008-0093747

(51) Int. Cl. H03K 5/00

(52) U.S. Cl. 327/554

(57) ABSTRACT

An integrated tracking filter includes: an amplifying unit having first to third terminals, the first terminal being connected to an input stage and the second terminal being connected to an output stage, and amplifying a signal from the input stage; a loading unit connected between a power source stage and the second terminal of the amplifying unit; a current source connected between the third terminal of the amplifying unit and a ground; and a switched LC filter unit connected between the third terminal of the amplifying unit and the ground and varying a pass band of the signal.

### CROSS-REFERENCE TO RELATED APPLICATIONS

This application claims the priority of Korean Patent Application No. 2008-0093747 filed on Sep. 24, 2008, in the Korean Intellectual Property Office, the disclosure of which is incorporated herein by reference.

### BACKGROUND OF THE INVENTION

1. Field of the Invention

The present invention relates to an integrated tracking filter adaptive to a television tuner and, more particularly, to an integrated tracking filter capable of integrating all the elements other than an inductor and controlling a filtering band independently from a tuning voltage of a voltage controlled oscillator (VCO).

2. Description of the Related Art

In general, a tuner of a television system should process broadband signals of 40 MHz to 900 MHz to amplify reception signals and selectively restore only a signal of a desired channel.

The related art single conversion tuner includes a plurality of external elements including a low noise amplifier (LNA). Specifically, the tuner uses an LNA using 5V of supply voltage, is formed of linear compound semiconductor that can overcome a poor channel environment, and configures a resonance tank of a VCO by using a varactor diode of high voltage to process only a signal of a desired channel because broadband signals of 40 MHz to 900 MHz are inputted thereto.

In addition, in the tuner, a tracking filter of an RF stage is controlled by using a tuning voltage generated for a channel selection. Such related art tracking filter is configured by using an air coil-type element.

Meanwhile, recently, development of RF processing techniques allows integration of the resonance tank of the VCO within a semiconductor chip, and currently, chips mostly tend to have the resonance tank. In this case, generally, the resonance tank is configured to oscillate at a frequency higher than one desired to be used in consideration of the characteristics of an internal inductor, and it is divided to generate a desired frequency.

FIG. 1 illustrates the influence of an interferer (i.e., interference signal) with respect to a desired signal before and after the LNA performs amplifying. With reference to FIG. 1, in compliance with the channel requirements of the digital tuner, if, for example, a desired channel has 100 MHz, there is an interferer of a large signal at 50 MHz, and a signal is amplified by an LNA, then a problem would arise in that a secondary harmonic component of 50 MHz is added with the signal of the desired channel due to the non-linearity of the LNA, which possibly causes a problem that the signal is distorted.

In addition, in the related art, the linearity is satisfied with the external element LNA having a 5V supply voltage, but in order to implement an IC of a single tuner, an RF CMOS process is essential, and because the supply voltage is gradually reduced in line with the recent trend of low power consumption of the RF process, it is virtually impossible to physically implement an LNA that may satisfy the above-mentioned channel environment.

In an effort to resolve such shortcomings, various types of tuner structures have been proposed, of which an integration technique of a tracking filter to cancel the interferer receives much attention.

However, unlike the resonance tank of the VCO, the tracking filter cannot be divided for use, having much difficulty in implementation of the tracking filter within a chip. Even if the tracking filter is anyhow implemented, it cannot be adjusted with a tuning voltage of the varactor used for the resonance tank of the VCO.

In addition, the related art tracking filter has problems in that designing of a product and a fabrication process are difficult, a defect generation factor is large, and in particular, much personnel expenses for a unit cost are incurred.

### SUMMARY OF THE INVENTION

An aspect of the present invention provides an integrated tracking filter capable of integrating all the elements, excluding an inductor, and controlling a filtering band independently from a tuning voltage of a voltage controlled oscillator (VOC).

According to an aspect of the present invention, there is provided an integrated tracking filter including: an amplifying unit having first to third terminals, the first terminal being connected to an input stage and the second terminal being connected to an output stage, and amplifying a signal from the input stage; a loading unit connected between a power source stage and the second terminal of the amplifying unit; a current source connected between the third terminal of the amplifying unit and a ground; and a switched LC filter unit connected between the third terminal of the amplifying unit and the ground and varying a pass band of the signal.

The amplifying unit may include a MOS transistor having a gate, the first terminal, a drain, the second terminal, and a source, the third terminal.

The switched LC filter unit may include a plurality of switched filters, and each switched filter may include a switch unit connected to the source of the MOS transistor and operating according to a switching control signal; a capacitor unit selected by the switch unit; and an inductor connected between the capacitor unit and a ground.

The switch unit may include a plurality of switches connected to the source of the MOS transistor and operating according to the switching control signal.

The capacitor unit may include a plurality of capacitors each connected to each of the plurality of switches.

According to the present invention, all the elements, excluding the inductor, can be integrated, and a filtering band can be controlled independently from a tuning voltage of the VCO.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates the influence of an interferer on a desired signal before and after a low noise amplifier (LNA) performs amplifying;

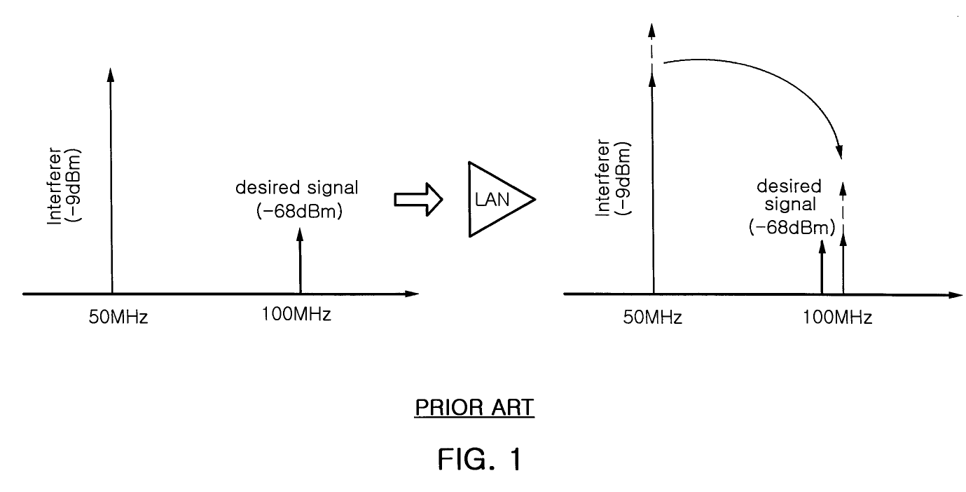

FIG. 2 is a circuit block diagram of an integrated tracking filter according to an exemplary embodiment of the present invention;

FIG. 3 is a graph showing response characteristics according to an exemplary embodiment of the present invention; and

FIG. 4 is a graph showing noise characteristics according to an exemplary embodiment of the present invention.

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

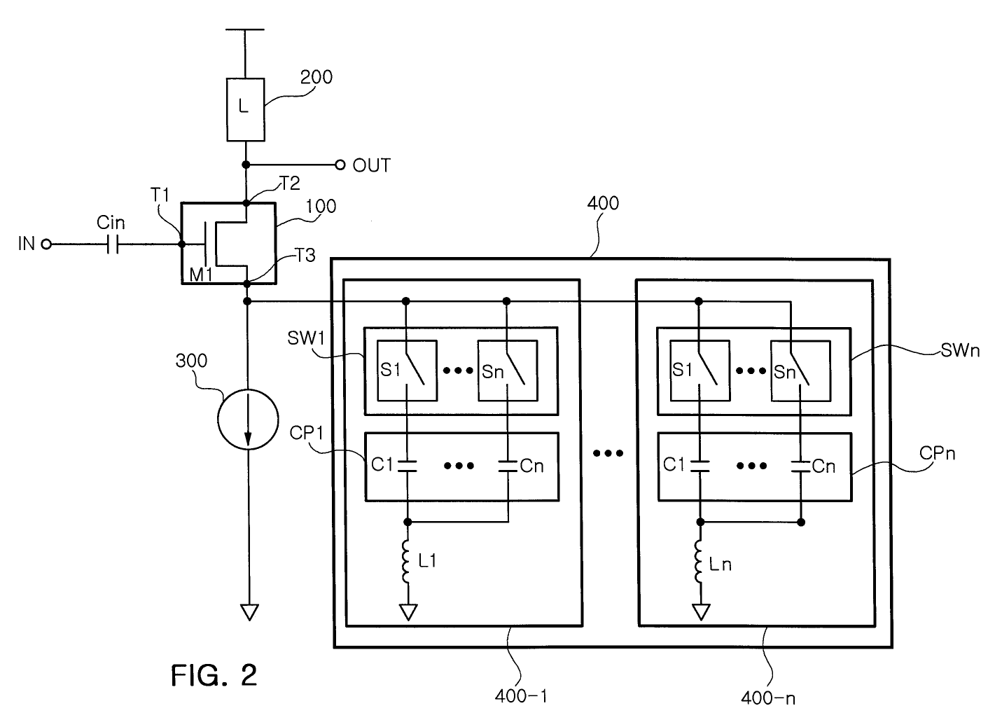

FIG. 2 is a circuit block diagram of an integrated tracking filter according to an exemplary embodiment of the present invention.

With reference to FIG. 2, the integrated tracking filter according to an exemplary embodiment of the present invention includes an amplifying unit 100, a loading unit 200, a current source 300, and a switched LC filter unit 400.

The amplifying unit 100 includes a first terminal T1, a second terminal T2, and a third terminal T3. The first terminal T1 is connected to an input stage IN, the second terminal T2 is connected to an output stage OUT. The amplifying unit 100 amplifies a signal from the input stage IN.

The loading unit 200 is connected between a power source stage VDD and the second terminal T2 of the amplifying unit 100.

The current source 300 is connected between the third terminal T3 of the amplifying unit 100 and a ground.

The switched LCD filter unit 400 is connected between the third terminal T3 of the amplifying unit 100 and the ground, to vary a pass band of the signal.

The amplifying unit includes a MOS transistor M1 having a gate, the first terminal T1, a drain, the second terminal T2, and a source, the third terminal T3.

The switched LC filter unit 400 includes a plurality of switched filters 400-1 to 400-n. Each of the plurality of switched filters 400-1 to 400-n includes a switch unit SW1 connected to a source of the MOS transistor M1 and operating according to a switching control signal, a capacitor unit CP1 selected by the switch unit SW1, and an inductor L1 connected between the capacitor unit CP1 and a ground.

When the plurality of switched filters 400-1 to 400-n include first to nth switched filters 400-1 to 400-n, the first switched filter 400-1 includes the switch unit SW1 connected to the source of the MOS transistor M1 and operating according to the switching control signal, the capacitor unit CP1 selected by the switch unit SW1, and the inductor L1 connected between the capacitor unit CP1 and the ground.

The nth switched filter 400-n includes a switch unit SWn connected to the source of the MOS transistor M1 and operating according to the switching control signal, a capacitor unit CPn selected by the switch unit SWn, and an inductor Ln connected between the capacitor unit CPn and the ground.

The switching control signal may be provided in various manners. For example, a switching control signal may be previously set for each variable frequency band, and the pre-set switching control signal may be provided to select a pass band of the switched LC filter unit 400.

Each of the switch units SW1 to SWn includes a plurality of switches S1 to Sn connected to the source of the MOS transistor M1 and operating according to the switching control signal.

Each of the capacitor units CP1 to CPn includes a plurality of capacitors C1 to Cn connected to the plurality of switches S1 to Sn.

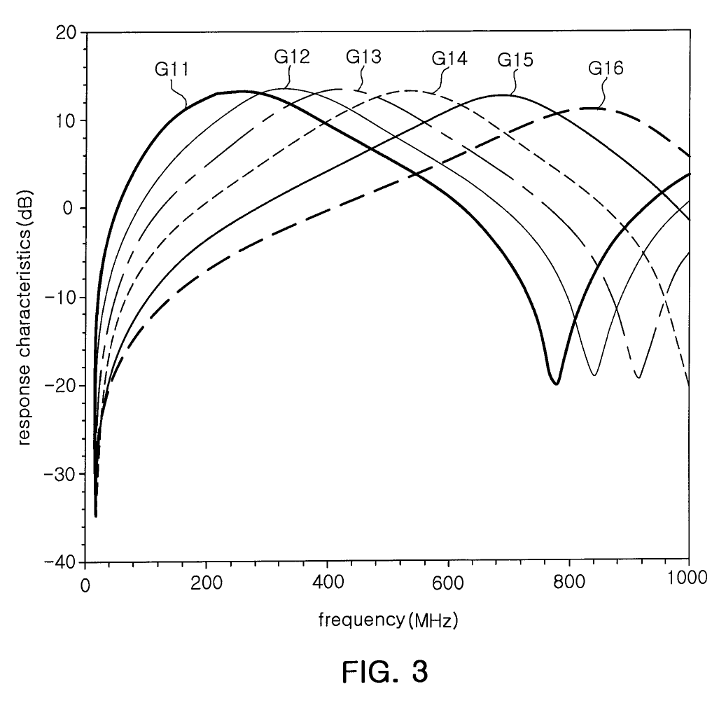

FIG. 3 is a graph showing response characteristics, namely, pass band variable characteristics, of the integrated tracking filter according to an exemplary embodiment of the present invention. As shown in FIG. 3, G11 represents a pass band with a mean frequency of about 240 Mhz, G12 represents a pass band with a mean frequency of about 320 MHz, G13 represents a pass band with a mean frequency of about 420 MHz, G14 represents a pass band with a mean frequency of about 560 MHz, G15 represents a pass band with a mean frequency of about 700 MHz, and G16 represents a pass band with a mean frequency of about 900 MHz.

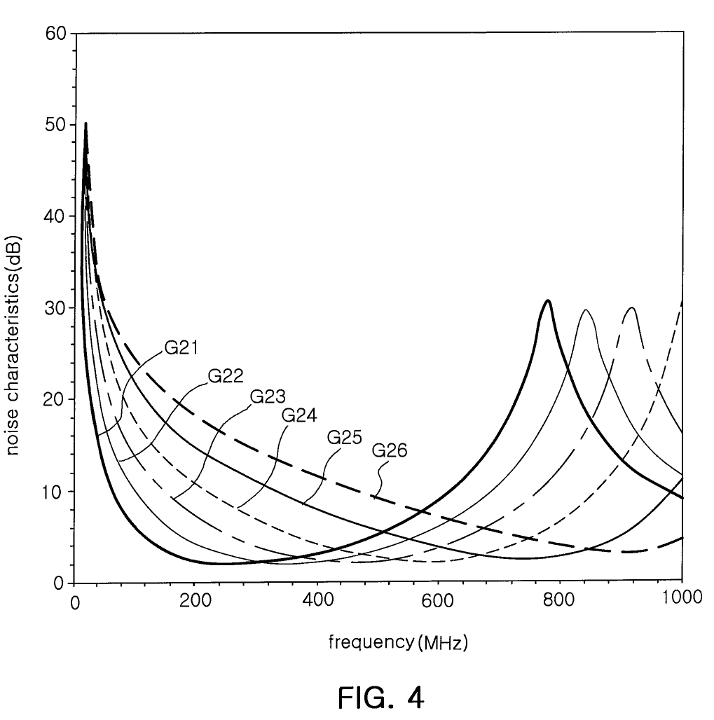

FIG. 4 is a graph showing noise characteristics G21 to G26 according to an exemplary embodiment of the present invention. As shown in FIG. 4, G21 represents a pass band with a mean frequency of about 240 MHz, G22 represents a pass band with a mean frequency of about 320 MHz, G23 represents a pass band with a mean frequency of about 420 MHz, G24 represents a pass band with a mean frequency of about 560 MHz, G25 represents a pass band with a mean frequency of about 720 MHz, and G26 represents a pass band with a mean frequency of about 900 MHz.

The operation and effect of the present invention will now be described in detail with reference to the accompanying drawings.

The integrated tracking filter according to an exemplary embodiment of the present invention will be described with reference to FIGS. 2 to 4 as follows. As shown in FIG. 2, the integrated tracking filter according to an exemplary embodiment of the present invention includes the amplifying unit 100, the loading unit 200, the current source 300, and the switched LCD filter unit 400.

First, when the amplifying unit 100 includes the MOS transistor M1 having the gate, the first terminal T1, the drain, the second terminal T2, and the source, the third terminal T3, the amplifying unit 100 amplifies a signal inputted to the gate via an input capacitor Cin.

Here, the loading unit 200 is connected between the power source stage VDD and the drain of the MOS transistor M1 of the amplifying unit 100, and determines an amplification gain of the amplifying unit 100.

The current source 300 is connected between the third terminal T3 of the amplifying unit 100 and the ground, and makes current uniformly flow to the MOS transistor M1 of the amplifying unit 100 to stabilize the operation.

The switched LC filter unit 400 is connected between the third terminal T3 of the amplifying unit 100 and the ground, and varies a pass band of the signal.

In detail, when the plurality of switched filters 400-1 to 400-n of the switched LCD filter unit 400 include the first to nth switched filters 400-1 to 400-n, the first switched filter 400-1 will now be described.

First, the first switched filter 400-1 includes the switch unit SW1 connected with the source of the MOS transistor M1 and operating according to the switching control signal, the capacitor unit CP1 selected by the switch unit SW1, and the inductor L1 connected between the capacitor unit CP2 and the ground. Each of the switch units SW1 to SWn includes the plurality of switches S1 to Sn connected to the source of the MOS transistor M1 and operating according to the switching control signal. Each of the capacitor units CP1 to CPn includes the plurality of capacitors C1 to Cn connected to the plurality of switches S1 to Sn.

Accordingly, one or more capacitors can be selected from among the plurality of capacitors C1 to Cn through the plurality of switches S1 to Sn, whereby the pass band can be varied as shown in FIGS. 3 and 4.

With reference to FIGS. 3 and 4, the pass band can be varied to 240 MHz, 320 Mhz, 420 Mhz, 560 MHz, 700 MHz, and 900 MHz by the integrated tracking filter according to the exemplary embodiment of the present invention, and in this case, the response characteristics are as shown in FIG. 3 and the noise characteristics are as shown in FIG. 4.

With reference to FIGS. 3 and 4, it is noted that the response characteristics at selected bands are higher than about 10 [dB], and the noise characteristics at the selected bands are lower than about 4 [dB].

As set force above, according to exemplary embodiments of the invention, all the elements, excluding the inductor, can be integrated, a filtering band can be controlled independently from a tuning voltage of the VCO, and thus, the filter varying the filtering band can be integrated.

While the present invention has been shown and described in connection with the exemplary embodiments, it will be apparent to those skilled in the art that modifications and variations can be made without departing from the spirit and scope of the invention as defined by the appended claims.

What is claimed is:

1. An integrated tracking filter comprising:
an amplifying unit having first to third terminals, the first terminal being connected to an input stage and the second terminal being connected to an output stage, and amplifying a signal from the input stage;
a loading unit connected between a power source stage and the second terminal of the amplifying unit;
a current source connected between the third terminal of the amplifying unit and a ground; and
a switched LC filter unit connected between the third terminal of the amplifying unit and the ground and varying a pass band of the signal.

2. The filter of claim 1, wherein the amplifying unit comprises a MOS transistor having a gate, the first terminal, a drain, the second terminal, and a source, the third terminal.

3. The filter of claim 2, wherein the switched LC filter unit comprises a plurality of switched filters, and each switched filter comprises:
a switch unit connected to the source of the MOS transistor and operating according to a switching control signal;
a capacitor unit selected by the switch unit; and
an inductor connected between the capacitor unit and a ground.

4. The filter of claim 3, wherein the switch unit comprises a plurality of switches connected to the source of the MOS transistor and operating according to the switching control signal.

5. The filter of claim 3, wherein the capacitor unit comprises a plurality of capacitors each connected to each of the plurality of switches.
